(19) United States
(12) Patent Application Publication
(10) Pub. No.: US 2026/0297737 A1
(43) Pub. Date: Oct. 1, 2026

(54) SUBSTRATE PROCESSING APPARATUS

(71) Applicant: Tokyo Electron Limited, Tokyo (JP)

(72) Inventors: Taichi MONDEN, Yamanashi (JP); Atsushi TANAKA, Yamanashi (JP)

(21) Appl. No.: 19/708,140

(22) Filed: Jun. 15, 2026

Related U.S. Application Data
(62) Division of application No. 18/522,825, filed on Nov. 29, 2023.

(30) Foreign Application Priority Data
Dec. 12, 2022 (JP) 2022-198124

(51) Int. Cl. C23C 16/44; C23C 16/34; C23C 16/455; C23C 16/52

(52) U.S. Cl. CPC C23C 16/4405; C23C 16/34; C23C 16/4408; C23C 16/45527; C23C 16/45544; C23C 16/52

(57) ABSTRACT

A substrate processing apparatus includes: a processing chamber; a gas supplier configured to supply a gas into the processing chamber; and a controller. The controller is configured to control the gas supplier to perform: a) supplying a fluorine-containing gas into the processing chamber to clean an inside of the processing chamber; b) after a), supplying a reducing gas into the processing chamber to purge the inside of the processing chamber; c) after b), supplying a raw material gas and a reducing gas into the processing chamber to form a precoat film; and d) after c), supplying a reducing gas into the processing chamber to purge the inside of the processing chamber before depositing on a subsequent substrate. The controller is further configured to control the gas supplier to perform and stop c) based on the flow rates of the fluorine-containing gas and the raw material gas.

### CROSS-REFERENCE TO RELATED APPLICATIONS

The present application is a divisional application of and claims the benefit of priority under 35 U.S.C. 120 of U.S. patent application Ser. No. 18/522,825 filed on Nov. 29, 2023, which is based on and claims priority to Japanese Patent Application No. 2022-198124 filed on Dec. 12, 2022. The contents of all of the aforementioned applications are incorporated herein by reference in their entirety.

### BACKGROUND OF THE INVENTION

### Field of the Invention

The present disclosure relates to a precoat method for a substrate processing apparatus and a substrate processing apparatus.

### Description of the Related Art

For example, Japanese Laid-Open Patent Publication No. 2004-288903 proposes a substrate processing apparatus for forming a Si₃N₄ film on a wafer by a thermal CVD method by supplying a deposition gas into a reactor in a deposition process. In the substrate processing apparatus, a cleaning process is executed in which the thin film deposited in the reactor through repeated deposition processes is removed and the inside of the reactor is cleaned. The cleaning process is performed by the thermal CVD method by supplying NF₃ gas into the reactor in a state where wafers are not housed. After the cleaning, NH₃ gas is supplied to the reactor in a state where wafers are not housed, while the pressure in the reactor is higher than the pressure in the reactor during the deposition process, and the reactor is purged. Further, after the purge, the deposition gas is supplied to the reactor in a state where wafers are not housed, while the pressure in the reactor is lower than the pressure in the reactor during the purge process, and a thin film is coated in the reactor by the thermal CVD method.

For example, Japanese Laid-Open Patent Publication No. 2010-34362 provides a substrate processing apparatus which can prevent by-products generated during substrate processing from flowing back to the gas supply line. The substrate processing apparatus includes: a processing chamber for processing a wafer; a process gas supply pipe that supplies process gas for processing the wafer into the processing chamber; a cleaning gas supply pipe that is connected so as to merge with the process gas supply pipe and supplies cleaning gas into the processing chamber for cleaning the inside of the processing chamber; and a controller that controls the cleaning gas supply line to supply the cleaning gas into the processing chamber, to remove deposits adhered to the processing chamber, and to clean the inside of the processing chamber.

### SUMMARY OF THE INVENTION

According to one aspect of the present disclosure, a precoat method for a substrate processing apparatus for depositing on a substrate using a raw material gas and a reducing gas is provided. The method includes: a) supplying a fluorine-containing gas into a processing chamber to clean an inside of the processing chamber; b) after a), supplying a reducing gas into the processing chamber to purge the inside of the processing chamber; c) after b), supplying a raw material gas and a reducing gas into the processing chamber to form a precoat film; and d) after c), supplying a reducing gas into the processing chamber to purge the inside of the processing chamber before depositing on a subsequent substrate.

### BRIEF DESCRIPTION OF THE DRAWINGS

FIG. 1 is a schematic cross-sectional view illustrating an example of a substrate processing apparatus according to an embodiment;

FIG. 2 is an example of a gas supply sequence in the substrate processing apparatus according to an embodiment;

FIG. 3 is a flowchart illustrating an example of a precoat method for the substrate processing apparatus according to an embodiment;

FIG. 4 is a diagram schematically illustrating a state on a surface of a part in a purge process of NH₃ gas, a precoat process, and a post-precoat process;

FIGS. 5A and 5B are an example of a number of particles generated by precoat methods of Reference Examples 1 to 3;

FIGS. 6A and 6B are an example of a number of particles generated by precoat methods of Reference Examples 1, 4, and 5;

FIGS. 7A and 7B are an example of a number of particles generated by precoat methods of Reference Examples 1 and 5 and of the first embodiment and the second embodiment;

FIGS. 8A, 8B, and 8C are an example of a graph illustrating the relationship between the temperature in the processing chamber and the mole number of surface material after the precoat process; and

FIG. 9 is an example of a graph illustrating the relationship between the pressure of NH₃ gas and the number of particles in the post-precoat process.

### DESCRIPTION OF THE EMBODIMENTS

Hereinafter, embodiments of the present disclosure will be described with reference to the accompanying drawings. In all accompanying drawings, the same components are denoted by the same reference numerals, and overlapping descriptions may be omitted.

### SUBSTRATE PROCESSING APPARATUS

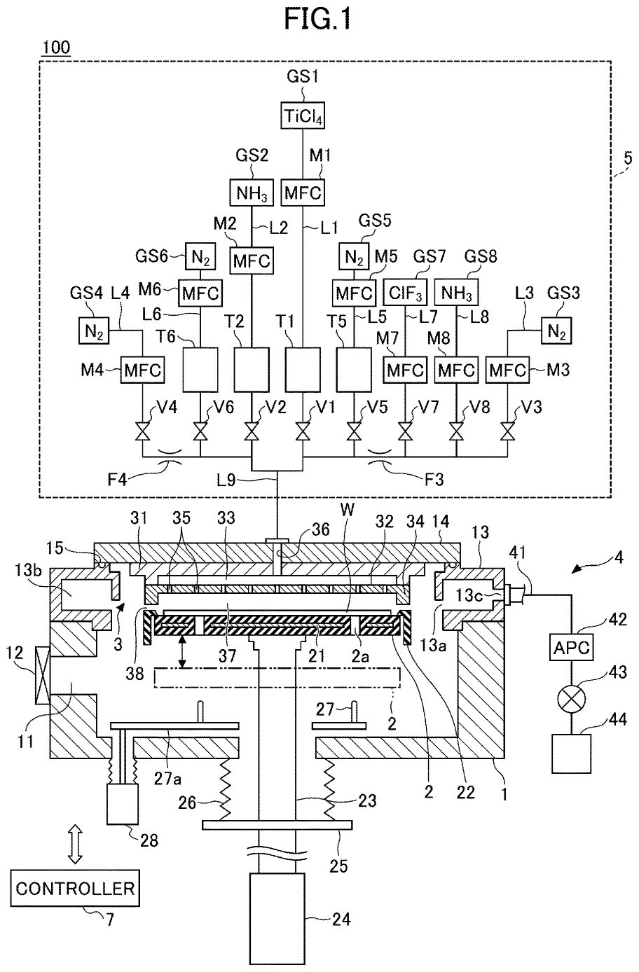

An example of a configuration of a substrate processing apparatus 100 according to one embodiment will be described with reference to FIG. 1. FIG. 1 is an example of a schematic cross-sectional view of the substrate processing apparatus 100 according to one embodiment.

The substrate processing apparatus 100 is an atomic layer deposition (ALD) apparatus for depositing a TiN film on a surface of a substrate W, for example a wafer, by supplying TiCl₄ gas, an example of a raw material gas, and NH₃ gas, an example of a reducing gas, to the substrate W.

The substrate processing apparatus 100 includes a processing chamber 1, a substrate mounting table 2, a shower head 3, an exhauster 4, a process gas supplier 5, and a controller 7.

The processing chamber 1 is composed of a metal such as aluminum and has a substantially cylindrical shape. A loading port 11 for carrying in or out the substrate W is formed on the side wall of the processing chamber 1. The loading port 11 can be opened and closed by a gate valve 12. An annular exhaust duct 13 having a substantially rectangular cross section is provided on the main body of the processing chamber 1. A slit 13a is formed along the inner peripheral surface of the exhaust duct 13. A ring-shaped exhaust space 13b is formed in the exhaust duct 13. An exhaust port 13c is formed on the outer wall of the exhaust duct 13. A top wall 14 is provided on the upper surface of the exhaust duct 13 so as to close the upper opening of the processing chamber 1. The space between the top wall 14 and the exhaust duct 13 is hermetically sealed with a seal ring 15.

The substrate mounting table 2 supports the substrate W horizontally in the processing chamber 1. The substrate mounting table 2 forms a disk shape of a size corresponding to the substrate W and is supported by a support member 23. The substrate mounting table 2 is composed of a ceramic material such as aluminum nitride (AlN) or a metal material such as aluminum or a nickel-based alloy, and a heater 21 for heating the substrate W is embedded therein. The heater 21 generates heat by supplying power from a heater power supply (not illustrated). The substrate W is controlled at a predetermined temperature by controlling the output of the heater 21 based on a temperature signal detected by a thermocouple (not illustrated) provided near the wafer mounting surface on the upper surface of the substrate mounting table 2.

The substrate mounting table 2 is provided with a cover member 22 made of a ceramic such as alumina to cover the outer peripheral region of the wafer mounting surface and the side surface of the substrate mounting table 2. The support member 23 extends downward from the center of the bottom of the substrate mounting table 2 and from the processing chamber 1, through a hole formed in the bottom wall of the processing chamber 1, and the lower end thereof is connected to the lifting mechanism 24. The lifting mechanism 24 allows the substrate mounting table 2 to move upward and downward via the support member 23 between the processing position illustrated in FIG. 1 and the transfer position below the processing position, indicated in a two-dot chain line, where the wafer can be transferred. A flange 25 is attached to the support member 23 below the processing chamber 1. A bellows 26 is provided between the bottom of the processing chamber 1 and the flange 25, which separates the atmosphere inside the processing chamber 1 from the outside air and expands and contracts with the lifting and lowering operation of the substrate mounting table 2.

Three (only two illustrated) wafer support pins 27 are provided near the bottom of the processing chamber 1 so as to protrude upward from the lifting plate 27a. The wafer support pins 27 can be lifted and lowered via the lifting plate 27a by the lifting mechanism 28 provided below the processing chamber 1, and are inserted into the through holes 2a provided in the substrate mounting table 2 at the transfer position so as to protrude and retract with respect to the upper surface of the substrate mounting table 2. By lifting and lowering the wafer support pins 27 in this manner, the substrate W is transferred between the wafer transfer mechanism (not illustrated) and the substrate mounting table 2.

The shower head 3 supplies the process gas into the processing chamber 1 like a shower. The shower head 3 is made of metal, is provided so as to face the substrate mounting table 2, and has a diameter almost the same as that of the substrate mounting table 2. The shower head 3 includes a body 31 fixed to the top wall 14 of the processing chamber 1 and a shower plate 32 connected under the body 31. A gas diffusion space 33 is formed between the body 31 and the shower plate 32. A gas introduction hole 36 is provided in the gas diffusion space 33 so as to penetrate the center of the body 31 and the top wall 14 of the processing chamber 1. An annular projection 34 projecting downward is formed on the peripheral edge of the shower plate 32. Gas discharge holes 35 are formed on a flat surface of the shower plate 32 inside the annular projection 34.

When the substrate mounting table 2 is in the processing position, a processing space 37 is formed between the shower plate 32 and the substrate mounting table 2. The annular projection 34 and the upper surface of the cover member 22 of the substrate mounting table 2 are close to each other to form an annular gap 38.

The exhauster 4 exhausts the inside of the processing chamber 1. The exhauster 4 includes an exhaust line 41, a pressure adjuster (auto pressure controller: APC) 42, a valve 43, and a vacuum pump 44. One end of the exhaust line 41 is connected to an exhaust port 13c of the exhaust duct 13, and the other end is connected to an intake port of the vacuum pump 44. Between the exhaust duct 13 and the vacuum pump 44, the pressure adjuster 42 and the valve 43 are provided in order from upstream. The pressure adjuster 42 adjusts the fluid conductance of the exhaust path to adjust the pressure of the processing space 37. The valve 43 switches the opening and closing of the exhaust line 41. In processing, the gas in the processing space 37 reaches the exhaust space 13b of the exhaust duct 13 through the annular gap 38 and the slit 13a, and is exhausted from the exhaust port 13c of the exhaust duct 13 through the exhaust line 41 by the vacuum pump 44 of the exhauster 4.

The process gas supplier 5 includes a raw material gas supply line L1, a reducing gas supply line L2, a first continuous N₂ gas supply line L3, a second continuous N₂ gas supply line L4, a first purge line L5, and a second purge line L6. Further, the process gas supplier 5 includes a cleaning gas supply line L7 and an ammonia purge gas supply line L8.

The raw material gas supply line L1 extends from a raw material gas supply source GS1, which is a supply source of a metal-containing gas, for example, TiCl₄ gas, and is connected to a confluence pipe L9. The confluence pipe L9 is connected to the gas introduction hole 36. The raw material gas supply line L1 is provided with a mass flow controller M1, a buffer tank T1, and an opening/closing valve V1 in order from the raw material gas supply source GS1 side. The mass flow controller M1 controls the flow rate of the TiCl₄ gas flowing through the raw material gas supply line L1. The buffer tank T1 temporarily stores the TiCl₄ gas and supplies the required TiCl₄ gas in a short time. The opening/closing valve V1 switches the supply/stop of the TiCl₄ gas during the atomic layer deposition (ALD) process.

The reducing gas supply line L2 extends from a reducing gas supply source GS2, which is a supply source of a reducing gas (a nitrogen-containing gas), for example, NH₃ gas, and is connected to the confluence pipe L9. The reducing gas supply line L2 is provided with a mass flow controller M2, a buffer tank T2, and an opening/closing valve V2 in order from the reducing gas supply source GS2 side. The mass flow controller M2 controls the flow rate of the NH₃ gas flowing through the reducing gas supply line L2. The buffer tank T2 temporarily stores the NH₃ gas and supplies the required NH₃ gas in a short time. The opening/closing valve V2 switches the supply/stop of the NH₃ gas during the ALD process.

The first continuous N₂ gas supply line L3 extends from a N₂ gas supply source GS3, which is a supply source of N₂ gas, and is connected to the raw material gas supply line L1. Thus, the N₂ gas is supplied to the raw material gas supply line L1 via the first continuous N₂ gas supply line L3. The first continuous N₂ gas supply line L3 constantly supplies the N₂ gas during deposition by the ALD method, which functions as a carrier gas for TiCl₄ gas and also as a purge gas. The first continuous N₂ gas supply line L3 is provided with a mass flow controller M3, an opening/closing valve V3, and an orifice F3 in order from the N₂ gas supply source GS3 side. The mass flow controller M3 controls the flow rate of the N₂ gas flowing through the first continuous N₂ gas supply line L3. The orifice F3 prevents the relatively large flow rate of gas supplied by the buffer tanks T1 and T5 from flowing back to the first continuous N₂ gas supply line L3.

The second continuous N₂ gas supply line L4 extends from a N₂ gas supply source GS4, which is a supply source of N₂ gas, and is connected to the reducing gas supply line L2. Thus, the N₂ gas is supplied to the reducing gas supply line L2 via the second continuous N₂ gas supply line L4. The second continuous N₂ gas supply line L4 constantly supplies the N₂ gas during deposition by the ALD method, which functions as a carrier gas for NH₃ gas and also as a purge gas. The second continuous N₂ gas supply line L4 is provided with a mass flow controller M4, an opening/closing valve V4, and an orifice F4 in order from the N₂ gas supply source GS4 side. The mass flow controller M4 controls the flow rate of the N₂ gas flowing through the second continuous N₂ gas supply line L4. The orifice F4 prevents the relatively large flow rate of gas supplied by the buffer tanks T2 and T6 from flowing back to the second continuous N₂ gas supply line L4.

The first purge line L5 extends from a N₂ gas supply source GS5, which is a supply source of N₂ gas, and is connected to the first continuous N₂ gas supply line L3. Thus, the N₂ gas is supplied to the raw material gas supply line L1 via the first purge line L5 and the first continuous N₂ gas supply line L3. The first purge line L5 supplies the N₂ gas only during the purge process during deposition in the ALD method. The first purge line L5 is provided with a mass flow controller M5, a buffer tank T5, and an opening/closing valve V5 in order from the N₂ gas supply source GS5 side. The mass flow controller M5 controls the flow rate of the N₂ gas flowing through the first purge line L5. The buffer tank T5 temporarily stores the N₂ gas and supplies the required N₂ gas in a short time. The opening/closing valve V5 switches the supply/stop of the N₂ gas during purging in the ALD process.

The second purge line L6 extends from a N₂ gas supply source GS6, which is a supply source of N₂ gas, and is connected to the second continuous N₂ gas supply line L4. Thus, the N₂ gas is supplied to the reducing gas supply line L2 via the second purge line L6 and the second continuous N₂ gas supply line L4. The second purge line L6 supplies the N₂ gas only during the purge process during deposition in the ALD method. The second purge line L6 is provided with a mass flow controller M6, a buffer tank T6, and an opening/closing valve V6 in order from the N₂ gas supply source GS6 side. The mass flow controller M6 controls the flow rate of the N₂ gas flowing through the second purge line L6. The buffer tank T6 temporarily stores the N₂ gas and supplies the required N₂ gas in a short time. The opening/closing valve V6 switches the supply/stop of the N₂ gas during purging in the ALD process.

The cleaning gas supply line L7 extends from a ClF₃ gas supply source GS7, which is a supply source of a cleaning gas (a fluorine-containing gas), for example, ClF₃ gas, and is connected to the first continuous N₂ gas supply line L3. Thus, the cleaning gas is supplied to the raw material gas supply line L1 via the cleaning gas supply line L7 and via the first continuous N₂ gas supply line L3. The cleaning gas supply line L7 is provided with a mass flow controller M7 and an opening/closing valve V7 in order from the ClF₃ gas supply source GS7 side. The mass flow controller M7 controls the flow rate of the cleaning gas flowing through the cleaning gas supply line L7. The opening/closing valve V7 switches the supply/stop of the ClF₃ gas during cleaning.

The ammonia purge gas supply line L8 extends from an NH₃ gas supply source GS8, which is a supply source of ammonia gas, and is connected to the first continuous N₂ gas supply line L3. Thus, the NH₃ gas is supplied to the raw material gas supply line L1 via the ammonia purge gas supply line L8 and the first continuous N₂ gas supply line L3. The ammonia purge gas supply line L8 is provided with a mass flow controller M8 and an opening/closing valve V8 in order from the NH₃ gas supply source GS8 side. The mass flow controller M8 controls the flow rate of the NH₃ gas flowing through the ammonia purge gas supply line L8. The opening/closing valve V8 switches the supply/stop of the NH₃ gas during the purge process using the NH₃ gas.

The controller 7 controls the operation of each part of the substrate processing apparatus 100. The controller 7 includes a central processing unit (CPU), a read only memory (ROM), and a random access memory (RAM). The CPU executes a desired process according to a recipe stored in a storage area such as the RAM. The recipe includes control information of the apparatus for process conditions. Examples of the control information include, for example, gas flow rate, pressure, temperature, and process time. The recipe and the program used by the controller 7 may be stored in, for example, a hard disk or a semiconductor memory. The recipe and the like may be stored in a portable computer-readable storage medium such as a CD-ROM or DVD, set in place, and read out.

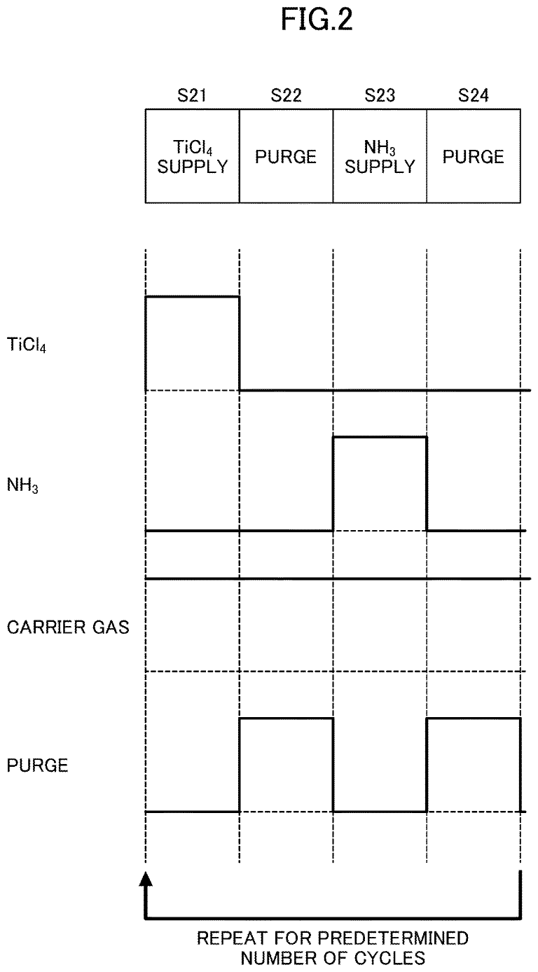

Next, a deposition process of a metal-containing film in the substrate processing apparatus 100 will be described with reference to the case where a TiN film is formed on the substrate W by the ALD process. FIG. 2 is a diagram illustrating an example of a gas supply sequence in the substrate processing apparatus 100 according to one embodiment.

First, the substrate W is transferred into the processing chamber 1 of the substrate processing apparatus 100. Specifically, the gate valve 12 is opened in a state in which the substrate mounting table 2 heated to a predetermined temperature (for example, 300° C. to 700° C.) by the heater 21 is lowered to the transfer position (indicated by a two-dot chain line in FIG. 1). Subsequently, the substrate W is conveyed into the processing chamber 1 through the loading port 11 by the transfer arm (not illustrated) and supported by the wafer support pins 27. When the transfer arm is evacuated from the loading port 11, the gate valve 12 is closed. The wafer support pins 27 are lowered to place the substrate W on the substrate mounting table 2. Subsequently, the substrate mounting table 2 is raised to the processing position (indicated by a solid line in FIG. 1), and the inside of the processing chamber 1 is depressurized to a predetermined vacuum degree. Thereafter, the opening/closing valves V3 and V4 are opened, and the opening/closing valves V1, V2, and V5 to V8 are closed. Thus, the N₂ gas is supplied into the processing chamber 1 from the N₂ gas supply sources GS3 and GS4 through the first continuous N₂ gas supply line L3 and the second continuous N₂ gas supply line L4 to increase the pressure and stabilize the temperature of the substrate W on the substrate mounting table 2. At this time, TiCl₄ gas is supplied into the buffer tank T1 from the raw material gas supply source GS1, and the pressure in the buffer tank T1 is maintained at a substantially constant level. The N₂ gas is supplied into the buffer tanks T5 and T6 from the N₂ gas supply sources GS5 and GS6, and the pressure in the buffer tanks T5 and T6 is maintained at a substantially constant level.

Subsequently, the TiN film is deposited by the ALD process using the TiCl₄ gas and the NH₃ gas. The ALD process repeats a TiCl₄ supply process S21, a first purge process S22, an NH₃ supply process S23, and a second purge process S24 for a predetermined cycle to form a TiN film having a desired film thickness on the substrate W.

The TiCl₄ supply process S21 is a process of supplying the TiCl₄ gas into the processing space 37. In the TiCl₄ supply process S21, N₂ gas (continuous N₂ gas) is supplied from the N₂ gas supply sources GS3 and GS4 through the first continuous N₂ gas supply line L3 and the second continuous N₂ gas supply line L4 with the opening/closing valves V3 and V4 open. The TiCl₄ gas is supplied from the raw material gas supply source GS1 through the raw material gas supply line L1 to the processing space 37 in the processing chamber 1 by opening the opening/closing valve V1. At this time, the TiCl₄ gas is temporarily stored in the buffer tank T1 and then supplied into the processing chamber 1. As a result, the TiCl₄ gas is adsorbed on the surface of the substrate W.

The first purge process S22 is a process of purging the excess TiCl₄ gas and the like in the processing space 37. In the first purge process S22, the opening/closing valve V1 is closed to stop the supply of TiCl₄ gas while the supply of the N₂ gas (continuous N₂ gas) through the first continuous N₂ gas supply line L3 and the second continuous N₂ gas supply line L4 is continued. The opening/closing valves V5 and V6 are also opened. Thus, the N₂ gas is supplied from the N₂ gas supply sources GS5 and GS6 to the processing space 37 in the processing chamber 1 via the first purge line L5 and the second purge line L6. At this time, the N₂ gas is supplied to the processing chamber 1 after being temporarily stored in the buffer tanks T5 and T6, so that a relatively large flow rate can be supplied. Thus, excess TiCl₄ gas and the like in the processing space 37 are purged.

The NH₃ supply process S23 is a process of supplying the NH₃ gas into the processing space 37. In the NH₃ supply process S23, the opening/closing valve V2 is opened in a state where the supply of the N₂ gas (continuous N₂ gas) through the first continuous N₂ gas supply line L3 and the second continuous N₂ gas supply line L4 is continued. The opening/closing valves V5 and V6 are closed. Thus, the NH₃ gas is supplied to the processing space 37 from the reducing gas supply source GS2 through the reducing gas supply line L2. At this time, the NH₃ gas is temporarily stored in the buffer tank T2 and then supplied into the processing chamber 1. Thus, the TiCl₄ adsorbed on the substrate W is reduced. The flow rate of the NH₃ gas at this time can be set to a sufficient amount for the reduction reaction to occur.

The second purge process S24 is a process of purging excess NH₃ gas in the processing space 37. In the second process of supplying N₂ gas, the opening/closing valve V2 is closed to stop the supply of the NH₃ gas while the supply of the N₂ gas (continuous N₂ gas) through the first continuous N₂ gas supply line L3 and the second continuous N₂ gas supply line L4 is continued. The opening/closing valves V5 and V6 are opened. Thus, the N₂ gas is supplied from the N₂ gas supply sources GS5 and GS6 to the processing space 37 in the processing chamber 1 via the first purge line L5 and the second purge line L6. At this time, the N₂ gas is supplied to the processing chamber 1 after being temporarily stored in the buffer tanks T5 and T6, so that a relatively large flow rate can be supplied. Thus, excess NH₃ gas and the like in the processing space 37 is purged.

Hereinafter, the steps S21 to S24 are repeated for a predetermined cycle to form a TiN film having a desired film thickness on the substrate W. In the depositing process of the substrate W described above, a film is also deposited on the inner wall of the processing chamber 1 and on the parts in the processing chamber 1. The deposited film is peeled off into particles, which affect the depositing process of the substrate W. Therefore, cleaning and coating with a precoat film are performed under predetermined conditions.

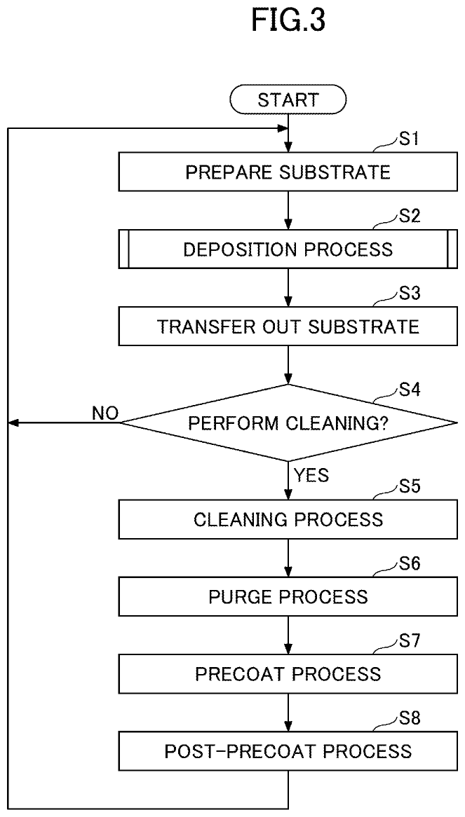

FIG. 3 is a flowchart illustrating an example of a precoat process of the substrate processing apparatus 100 according to one embodiment. Step S21 to S24 in FIG. 2 are specific examples of the deposition process performed in step S2 for the substrate W prepared on the substrate mounting table 2 in step S1 of FIG. 3. After the TiN film is formed on the substrate W, the substrate W is performed in step S3.

### CLEANING PROCESS

After carrying out the substrate W, in step S4, the controller 7 determines whether to execute the process of cleaning the inside of the processing chamber 1. For example, the controller 7 may determine whether to execute cleaning based on whether the number of processed substrates W after the most recent cleaning has exceeded a certain number. The number of the processed substrates W may be set in advance to the number that needs to be cleaned.

When the controller 7 determines in step S4 that cleaning is not performed, the controller 7 returns to step S1, carries in a subsequent substrate W, and carries out the substrate W after forming a TiN film on the substrate W in steps S2 and S3.

When it is determined in step S4 that cleaning is to be performed, the controller 7 proceeds to step S5 and supplies ClF₃ gas, which is an example of a fluorine-containing gas, into the processing chamber 1 to clean the inside of the processing chamber 1. The processing chamber 1 to be cleaned includes parts (a gas diffusion space 33, a gas discharge hole 35, and the like) constituting a gas flow path.

In the cleaning process in step S5, the opening/closing valve V7 illustrated in FIG. 1 is opened, and the other opening/closing valves V1 to V6 and V8 are closed. Thus, the ClF₃ gas is supplied to the processing space 37 from the ClF₃ gas supply source GS7 through the cleaning gas supply line L7. Thus, the TiN film in the processing chamber 1 can be removed.

### PURGE PROCESS

After the cleaning process, the controller 7 supplies ammonia (NH₃) gas, which is an example of a reducing gas, into the processing chamber 1 in step S6, and purges the inside of the processing chamber 1. The reducing gas supplied in step S6 may be the same gas as the reducing gas used for deposition of the substrate W. In the present embodiment, the reduction gas supplied in step S6 and the reduction gas used for depositing on the substrate W are both the NH₃ gas.

In the purge process in step S6, the ClF₃ gas and the like adsorbed and remaining in the processing space 37 and the processing chamber 1 is purged. In the purge process in step S6, the opening/closing valve V7 is closed to stop the supply of the ClF₃ gas. The opening/closing valve V8 is also opened. As a result, the NH₃ gas is supplied to the processing space 37 from the NH₃ gas supply source GS8 through the ammonia purge gas supply line L8. At this time, the NH₃ gas is supplied at a constant flow rate of, for example, 9,000 sccm for three hours. The NH₃ gas may be supplied at a large flow of 9,000 sccm or more. The NH₃ gas may be supplied at a constant flow rate for three hours or more. In the purge process of step S6, the NH₃ gas is not stored in the buffer tank before being supplied. The reason for this is that, in the purge process of step S6, it is important to increase the NH₃ gas supply time to a certain extent in order to accelerate the chemical reaction represented by the following chemical reaction formula (1). When the NH₃ gas is supplied after being stored in the buffer tank, the NH₃ gas is not supplied while the NH₃ gas is stored in the buffer tank, so that the NH₃ gas supply time is shortened. Thus, when the NH₃ gas is supplied after being stored in the buffer tank, the reaction is less likely to be accelerated.

### Chemical Reaction Formula (1) in Purge Process

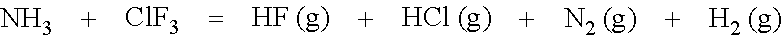

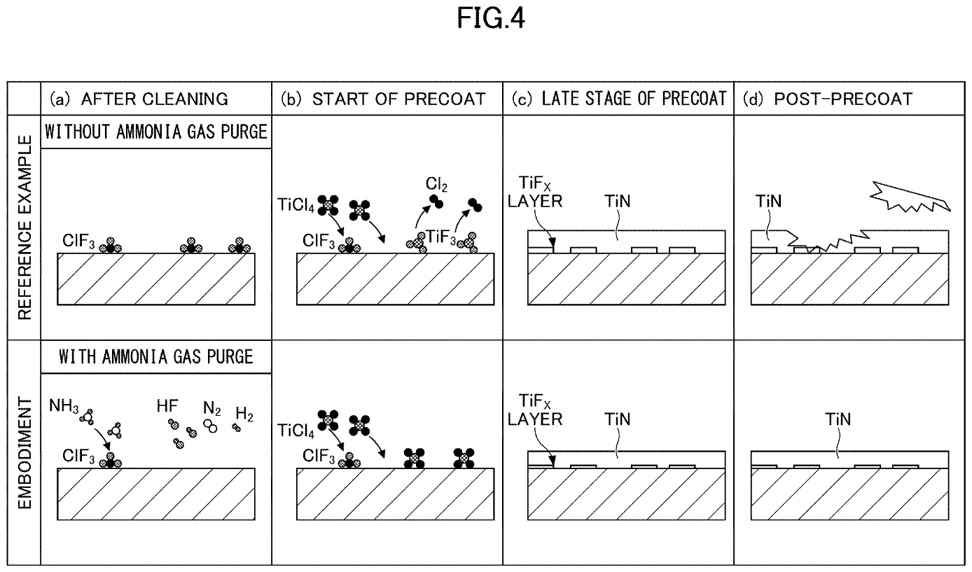

FIG. 4 is a diagram schematically illustrating a gas adsorption state on the surface of a part (a gas flow path, and the like) in the processing chamber 1 in the purge process of the NH₃ gas (FIG. 3, step S6), the precoat process (step S7), and the post-precoat process (step S8). The upper row of FIG. 4 presents the surface state of the part at each time point of: (a) after the cleaning (without NH₃ gas purge); (b) start of the precoat; (c) late stage of the precoat; and (d) the post-precoat; in Reference Example. The lower row of FIG. 4 presents the surface state of the part at each time point of: (a) after the cleaning (with NH₃ gas purge); (b) start of the precoat; (c) late stage of the precoat; and (d) the post-precoat; in the embodiment.

In Reference Example, (a) after the cleaning process, the purge process using the NH₃ gas (step S6 in FIG. 3) is not performed. In this case, the ClF₃ of the cleaning gas is adsorbed on the surface of the part.

In contrast, in the embodiment, (a) after the cleaning process, the purge process using the NH₃ gas (step S6 in FIG. 3) is performed. At this time, the NH₃ and the ClF₃ react according to the chemical reaction formula (1) to produce HF gas, HCl gas, N₂ gas, H₂ gas, and the like, and these gases are volatilized. As a result, the residual adsorbed ClF₃ is discharged as HF gas and the like, and as illustrated in FIG. 4 (a), in the embodiment, less ClF₃ is adsorbed on the surface of the part compared to Reference Example.

### PRECOAT PROCESS

Returning to FIG. 3, after the purge process in step S6, the controller 7 supplies the raw material gas and the reduction gas into the processing chamber 1 in step S7 to form a precoat film. The raw material gas and the reduction gas supplied in the precoat process are preferably the same gas as the raw material gas and the reduction gas used for the deposition on the substrate W. Thus, the same film (for example, a TiN film) as the film formed in the deposition process of the substrate W is formed as a precoat film on the parts in the processing chamber 1, and the deposition environment of the substrate W can be stabilized.

For example, in the precoat process, the TiN film is formed using the TiCl₄ gas and the NH₃ gas by the deposition method described with reference to FIGS. 1 and 2.

As illustrated in FIG. 4 (a), in the embodiment, by performing the purge process of the NH₃ gas after the cleaning process, the amount of ClF₃ adsorbed on the surface of the part is small compared to Reference Example without the purge process. Therefore, from the start of the precoat process illustrated in FIG. 4 (b), in Reference Example, the TiCl₄ gas is supplied in a state in which the ClF₃ is largely adsorbed, and the reaction represented by the following chemical reaction formula (2) occurs.

### Chemical Reaction Formula (2) in Precoat Process

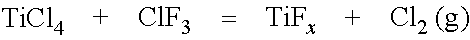

In Reference Example, because the ClF₃ is adsorbed on the surface of the part, a large amount of TiFₓ is generated. TiFₓ is a solid when it is TiF₃ and a gas when it is TiF₄. In Reference Example, a larger amount of TiF₃ is produced than in the embodiment, and at the late stage of the precoat process illustrated in FIG. 4 (c), a TiN film, which is a precoat film, is deposited on the TiFₓ layer.

In contrast, in the embodiment, because the amount of the ClF₃ adsorbed is decreased due to the purge process of the NH₃ gas, less TiFₓ is produced compared to Reference Example. Therefore, in the embodiment, less TiF₃ is produced compared to Reference Example, and at the late stage of the precoat process illustrated in FIG. 4 (c), a TiN film, which is the precoat film, is deposited on the TiFₓ layer, which is less (thinner) compared to Reference Example.

The less the TiFₓ layer at the interface of the parts, the higher the adhesion of the TiN film, which is the precoat film, and the harder it is for the TiN film to peel off. Thus, particles can be decreased.

### POST-PRECOAT PROCESS

Returning to FIG. 3, after the precoat process in step S7, the controller 7 supplies the reducing gas into the processing chamber 1 and purges the inside of the processing chamber 1 before depositing on a subsequent substrate W in step S8. After the process in step S8, the process returns to step S1, and a TiN film of the subsequent substrate is deposited in steps S1 to S3.

In the post-precoat process, NH₃ gas is used as the reducing gas to be supplied. In the post-precoat process, the NH₃ gas is temporarily stored in the buffer tank, and a high pressure of approximately 400 Torr (53,329 Pa) of the NH₃ gas is supplied from the buffer tank.

Specifically, with reference to FIG. 1, the opening/closing valve V2 is opened and other opening/closing valves are closed. Thus, the NH₃ gas is supplied to the processing space 37 from the reducing gas supply source GS2 via the reducing gas supply line L2. At this time, the NH₃ gas is temporarily stored in the buffer tank T2 and then supplied into the processing chamber 1.

The time for temporarily storing the NH₃ gas in the buffer tank T2 is approximately 0.7 seconds, and the time for supplying the NH₃ gas stored in the buffer tank T2 into the processing chamber 1 is approximately 0.3 seconds. In the post-precoat process, the supply of the NH₃ gas is stopped while the NH₃ gas is stored in the buffer tank T2 by closing the opening/closing valve V2, and then the opening/closing valve V2 is opened to supply the NH₃ gas stored in the buffer tank T2 into the processing chamber 1 at high flow rate. In other words, the pulse supply in which the NH₃ gas is supplied and stopped is performed. In the post-precoat process, the supply/stop of the NH₃ gas is repeated 1,200 times to supply a large flow of the NH₃ gas of approximately 9,000 sccm into the processing chamber 1 in approximately 20 minutes.

When the opening/closing valve V2 is opened, the NH₃ gas stored in the buffer tank T2 is supplied into the processing chamber 1 at high flow rate at a pressure of approximately 400 Torr. As a result, the weak part in the precoat film containing Cl remaining in the TiN film is removed by physically blowing them away with the NH₃ gas at high pressure. In addition, as illustrated in the chemical reaction formula (3), Cl in the precoat film reacts with NH₃, is reformed into HCl, and volatilizes, whereby Cl in the precoat film can also be removed. In this manner, by blowing a weak part of the precoat film away in advance in the post-precoat process immediately before the deposition and forming a strong precoat film, the generation of particles due to peeling of the precoat film in the deposition process can be decreased.

### Chemical Reaction Formula (3) in Post-Precoat Process

TiN+Cl₂ in the precoat film+NH₃═TiN+HCl(g)+N₂(g)

That is,

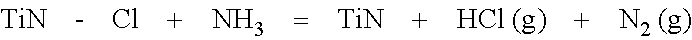

At this time, Cl is mostly residually adsorbed on TiN.

The NH₃ gas supplied in the post-precoat process does not need to be at a high pressure. The NH₃ gas supplied does not need to be at a large flow. When the NH₃ gas is not at a high pressure, the function of removing the weak part in the precoat film by physically blowing it away with the NH₃ gas at a high pressure is decreased, but the Cl in the precoat film reacts chemically with NH₃ and is reformed into HCl. Thus, a strong precoat film can be formed by volatilizing and removing HCl, and the generation of particles due to peeling of the precoat film in the deposition process can be decreased.

A large flow of N₂ gas and H₂ gas may be supplied together with the large flow of the NH₃ gas. When a large flow of H₂ gas is supplied, the N₂ gas is supplied from the first purge line L5 or the second purge line L6 illustrated in FIG. 1. A H₂ gas supply source (not illustrated), an MFC, a buffer tank, and an opening/closing valve may be provided to supply a large flow of H₂ gas from the H₂ gas supply source into the processing chamber 1.

In Reference Example illustrated in FIG. 4, in the post-precoat process illustrated in FIG. 4 (d), a high pressure NH₃ gas is supplied and a large flow of N₂ gas and H₂ gas is supplied. Then, because the TiFₓ layer at the interface is relatively large, the adhesion of the TiN film is decreased, and the TiN film of the precoat film is peeled off. As a result, particles are generated in the deposition process, which affects the deposition process of the substrate W.

In contrast, in the present embodiment, the precoat process is performed after reducing the ClF₃ that is residually adsorbed in the purge process using the NH₃ gas after the cleaning process. Therefore, because the ClF₃ that is residually adsorbed in the precoat process is decreased, the TiFₓ layer formed at the interface of the parts is decreased. As a result, the adhesion of the precoat film is higher compared to Reference Example. Therefore, even when a large flow of high pressure NH₃ gas is supplied and a large flow of N₂ gas and H₂ gas are supplied in the post-precoat process, the TiN film of the precoat film is less likely to peel off, and the generation of particles can be decreased in the deposition process.

### EXPERIMENTAL RESULT 1

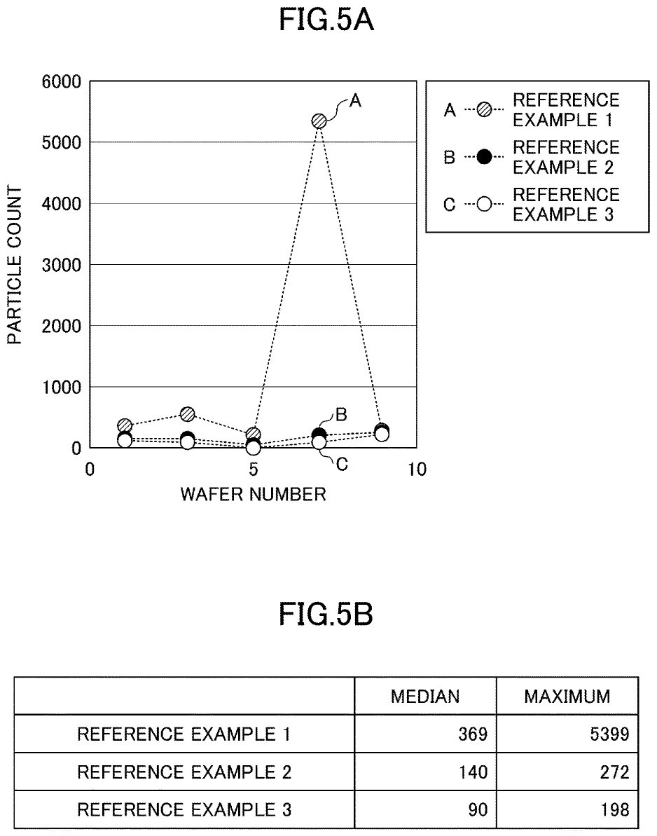

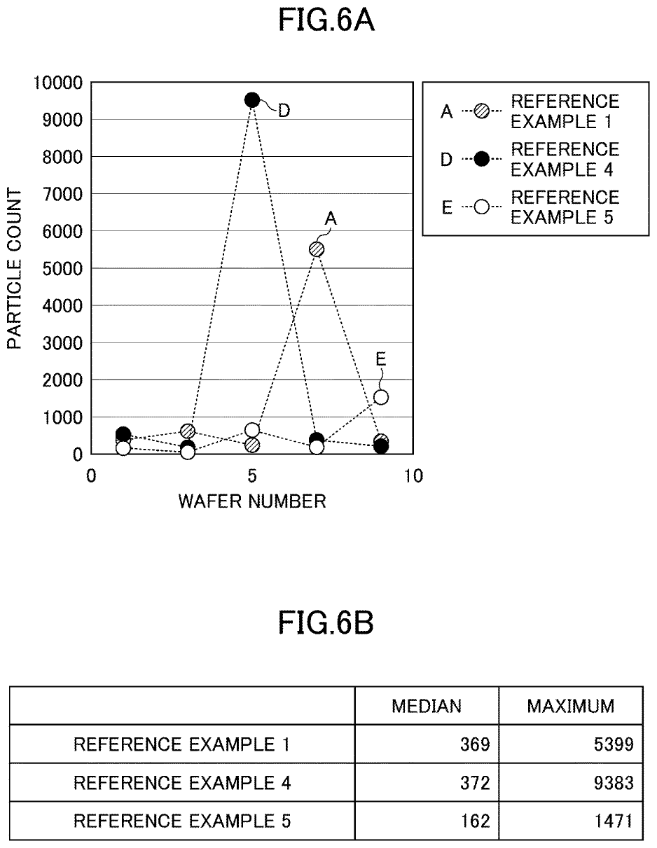

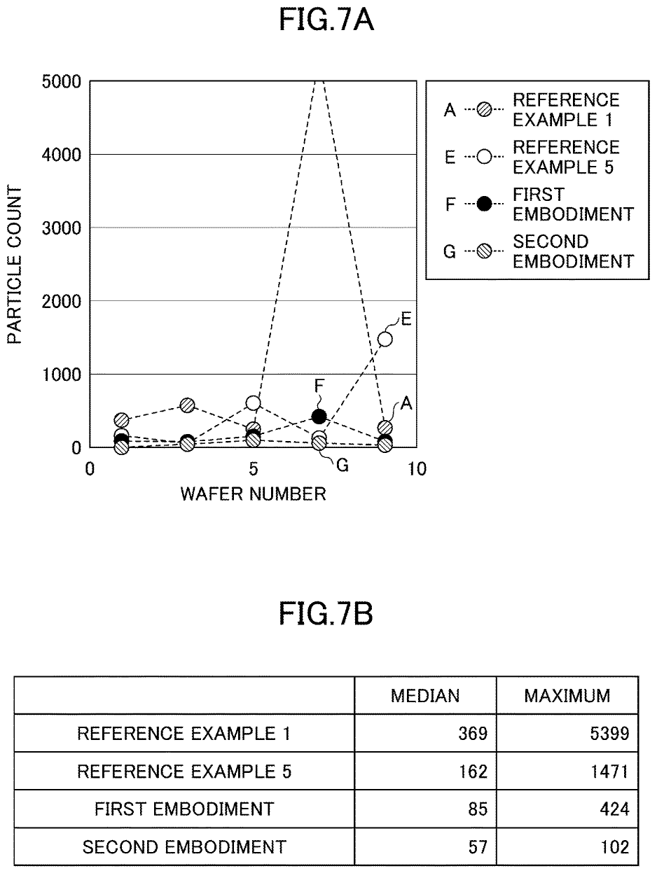

Referring to FIGS. 5A to 7B, an example of experimental results of the number of particles in Reference Example and the embodiment will be described. FIGS. 5A and 5B are an example of the number of particles generated by precoating of Reference Examples 1 to 3. FIGS. 6A and 6B are an example of the number of particles generated by precoating of Reference Examples 1, 4, and 5. FIGS. 7A and 7B are an example of the number of particles generated by the precoat method of Reference Examples 1, 5, the first embodiment, and the second embodiment. The numbers of substrates (wafers) on the horizontal axis of FIGS. 5A to 7B are assigned sequentially from the first wafer in the deposition process after the post-precoat process. The number of particles on the vertical axis of FIGS. 5A, 6A, and 7A is the number of particles on the processed wafer after the deposition process for each wafer number.

In Reference Example 1, after the cleaning process (step S5) of FIG. 3, the precoat process (step S7) was performed without the purge process (step S6), and a process of supplying a high pressure and large flow of N₂ gas was performed instead of the post-precoat process (step S8).

As indicated with a line A of FIG. 5A and in FIG. 5B, in Reference Example 1, the maximum number of particles was 5,399, the median was 369, and the number of particles was large. Because the gas flow rate was high in the large-flow process, particles due to TiN film peeling were generated frequently in the first approximately 10 substrates processed immediately after the precoating.

In Reference Example 2, after the cleaning process (step S5), N₂ purge was performed instead of the NH₃ purge process (step S6) of the present embodiment. In the purge process, a large flow of N₂ gas of approximately 1,000 sccm was supplied for five seconds, and a small flow of N₂ gas of approximately 300 sccm was supplied for five seconds alternately. A process of supplying a high pressure (450 Torr (60,000 Pa)) and a large flow of N₂ gas was performed for 48 hours instead of the post-precoat process (step S8).

As indicated with a line B of FIG. 5A and in FIG. 5B, in Reference Example 2, the maximum number of particles was 272 and the median was 140. That is, particles were decreased by removing the residual adsorbed ClF₃ by the N₂ purge. However, in Reference Example 2, the post-precoat process required 48 hours, and the productivity deteriorated.

In Reference Example 3, after the cleaning process (Step S5), N₂ purge was performed for 38 hours instead of the purge process (Step S6). In addition, no process was performed to substitute for the post-precoat process (Step S8).

As indicated with a line C of FIG. 5A and in FIG. 5B, in Reference Example 3, the maximum number of particles was 198 and the median was 90. That is, particles were decreased by removing the residual adsorbed ClF₃. However, in Reference Example 3, the purge process required 38 hours, and the productivity deteriorated.

In Reference Examples 2 and 3, the maximum number of particles was decreased to 300 or less. However, the productivity decreased significantly.

Next, Reference Examples 4 and 5 of FIGS. 6A and 6B will be described. Reference Example 1 of FIGS. 6A and 6B was under the same condition as Reference Example 1 of FIGS. 5A and 5B, and the same results are presented. In Reference Example 4, the same process as Reference Example 2 was performed, and a process of supplying a high pressure (450 Torr (60,000 Pa)) and a large flow of N₂ gas was performed for four hours instead of the post-precoat process (step S8). In Reference Example 5, the same process as Reference Example 3 was performed, and N₂ purge was performed for three hours instead of the purge process (step S6).

As indicated with lines D and E of FIG. 6A, and in FIG. 6B, in Reference Example 4, the maximum number of particles was 9,383 and the median was 372, and in Reference Example 5, the maximum number of particles was 1,471 and the median was 162. When the purging time of the N₂ gas was shortened to improve productivity, the maximum number of particles was 1,000 or more, and the number of particles could not be decreased.

Next, the first embodiment and the second embodiment of FIGS. 7A and 7B will be described. Reference Examples 1 and 5 of FIGS. 7A and 7B were under the same conditions as Reference Example 1 of FIGS. 5A and 5B and as Reference Example 5 of FIGS. 6A and 6B, and the same results are presented.

In the first embodiment, after the cleaning process (step S5) of FIG. 3, the purge process (step S6) was performed, and in the purge process (step S6), constant NH₃ gas was supplied at a large flow of 9,000 sccm for three hours. Next, the precoat process (step S7) was performed, and a large-flow process of supplying a high-pressure N₂ gas was performed instead of the post-precoat process (step S8).

As indicated with a line F of FIG. 7A and in FIG. 7B, in the first embodiment, the maximum number of particles was 424 and the median was 85. From the results, it was found that the residual ClF₃ was removed by purging NH₃ gas for approximately three hours after the cleaning process, and as a result, the formation of TiFₓ layer was suppressed in the early stage of precoating, and the adhesion of the precoat film was improved. As a result, the generation of particles due to the film peeling of the precoat film was decreased.

In the second embodiment, as in the first embodiment, in the purge process (step S6), constant NH₃ gas was supplied at a large flow of 9,000 sccm for three hours. Next, a precoat process (step S7) was performed, and a process of supplying a high pressure and a large flow of NH₃ gas was performed in the post-precoat process (step S8). In the post-precoat process (step S8), no gas other than NH₃ gas and N₂ gas from the first continuous N₂ gas supply line L3 and the second continuous N₂ gas supply line L4 was supplied.

As indicated with a line G of FIG. 7A and in FIG. 7B, in the second embodiment, the maximum number of particles was 102 and the median was 57. From the results, it was found that the number of particles can be decreased to a maximum of approximately 100 by removing the residual adsorbed ClF₃ by the purge process of the NH₃ gas (step S6) and purging the high pressure and large flow of NH₃ gas in the post-precoat process (step S8).

When ClF₃ remains on the surface of the parts in the processing chamber 1 in the cleaning process, a TiFₓ layer is formed on the surface at the early stage of forming the precoat film, and it becomes a cause of particle generation by the film peeling of the precoat film. In the first embodiment and the second embodiment, by performing the purge process using the NH₃ gas after the cleaning process, most of the residual adsorbed ClF₃ on the surface of the parts was removed, and the particles after the formation of the precoat film were decreased.

Further, after the precoat process, in Reference Example 5, the weak film part in the precoat film was detached and removed by the purge of the high pressure and large flow of N₂ gas. In contrast, in the second embodiment, the purge of the high pressure and large flow of NH₃ gas was performed. As a result, the TiN film of the precoat film was modified with the NH₃ gas to make the TiN film of the precoat film stronger while the weak film part in the precoat film was detached and removed. Accordingly, particles were further decreased. As a result, particles after the formation of the precoat film were decreased without compromising productivity.

### EXPERIMENTAL RESULT 2

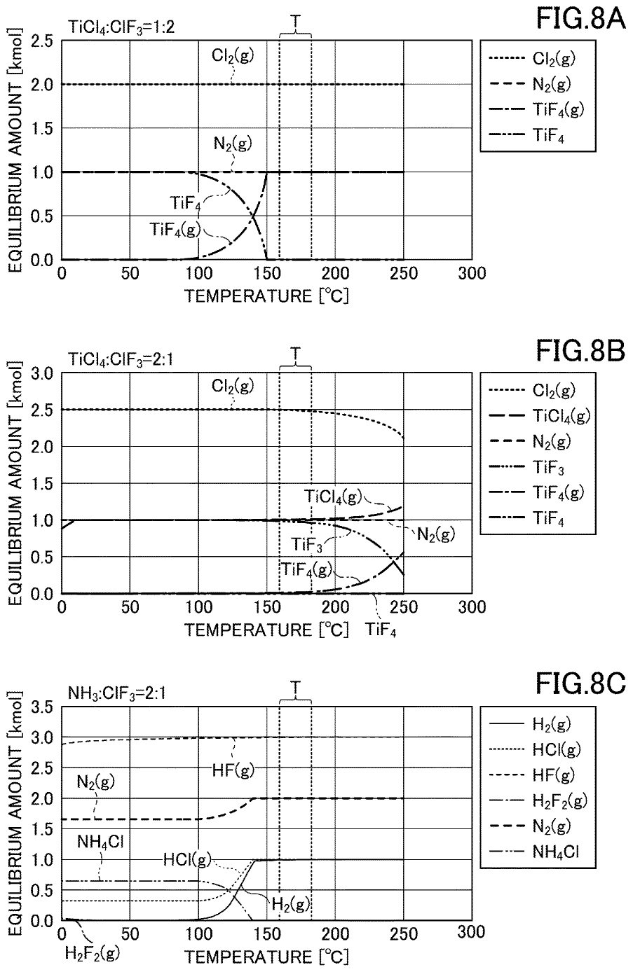

Next, with reference to FIGS. 8A to 8C, the relationship between the temperature in the processing chamber 1 and the mole number of material on the surface of the part by equilibrium composition calculation using thermodynamic calculation software will be described. FIGS. 8A to 8C are an example of a graph illustrating the relationship between the temperature in the processing chamber and the mole number of material on the surface after the precoat process and the purge process using the NH₃ gas.

In FIGS. 8A to 8C, the horizontal axis indicates the temperature in the processing chamber 1, and the vertical axis indicates the mole number of material (kmol) on the surface of the part. The temperature in the frame T in FIGS. 8A to 8C is the temperature in the processing chamber 1 after the precoat process and after the purge process using the NH₃ gas. Therefore, by observing the mole number at the temperature in the frame T, the surface condition of the part after the precoat process and after the purge process using the NH₃ gas can be determined.

As illustrated in FIG. 8C, when the flow rate ratio of NH₃ gas to ClF₃ gas is 2:1, in the surface state of the part after the purge process using the NH₃ gas, the mole number of HF (g) was large at the temperature of the frame T. In other words, in the purge process using the NH₃ gas after the cleaning process, the remaining ClF₃ was reacted with the NH₃ gas to form HF gas and vaporized. Accordingly, TiCl₄ gas can be supplied in the precoat process in a state where ClF₃ is decreased, and the adhesion of the precoat film can be enhanced in the precoat process.

When TiCl₄ gas is supplied in the precoat process to the surface of the part where a large amount of ClF₃ remains, ClF₃ reacts with the TiCl₄ gas to become TiF₃, which is difficult to volatilize, and adhesion occurs. In addition, as illustrated in FIG. 8B, when a flow rate ratio of TiCl₄ gas to ClF₃ gas is 2:1, as a result of the reaction of the ClF₃ on the surface of the part with the TiCl₄ gas, the mole number of TiF₃ is large on the surface of the part and the mole number of TiF₄ (g) is almost absent at the temperature in the frame T. Therefore, the TiFₓ produced does not volatilize as TiF₄ (g), and the TiN film of the precoat film is deposited in a state where the TiFₓ layer at the part interface remains. Then, in the post-precoat process after the precoat process, the TiN film of the precoat film is peeled off when a high pressure and a large flow of NH₃ gas is supplied, which causes particle generation.

In contrast, as illustrated in FIG. 8A, when the flow rate ratio of the TiCl₄ gas to the ClF₃ gas is 1:2, as a result of the reaction of the ClF₃ on the surface of the part with the TiCl₄ gas, the mole number of TiF₄ (g) is large on the surface of the part and the mole number of TiF₃ is absent at the temperature in the frame T. Therefore, the TiFₓ produced volatilizes as TiF₄ (g), and the TiN film of the precoat film is deposited on the TiFₓ layer in a state where the TiFₓ layer at the interface of the part is small. Then, in the post-precoat process after the precoat process, the TiN film of the precoat film is difficult to be peeled off when a high pressure and a large flow of NH₃ gas is supplied, and thus, particles can be decreased.

Therefore, when the flow rate of the fluorine-containing gas (ClF₃) supplied in the cleaning process is higher than the flow rate of the raw material gas (TiCl₄) supplied in the precoat process, the controller 7 may control to execute the precoat process. When the flow rate of the fluorine-containing gas supplied in the cleaning process is equal to or lower than the flow rate of the raw material gas, the controller 7 may control to stop the execution of the precoat process.

### EXPERIMENTAL RESULT 3

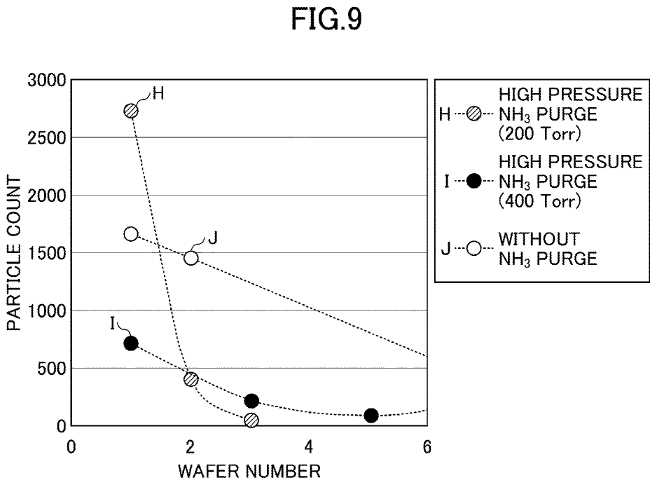

Next, the relationship between the pressure of NH₃ gas and the number of particles in the post-precoat process will be described with reference to FIG. 9. FIG. 9 is an example of a graph illustrating the relationship between the pressure of NH₃ gas and the number of particles in the post-precoat process according to an embodiment.

In the second embodiment illustrated in FIGS. 7A and 7B, a high pressure and a large flow of NH₃ gas was supplied in the post-precoat process. In FIG. 9, the pressure of NH₃ gas in the post-precoat process was controlled variably. The horizontal axis of the graph in FIG. 9 is the number of the substrate (wafer), and the vertical axis is the number of particles.

A line H in FIG. 9, which is an example of the second embodiment, indicates the number of particles when the pressure of the NH₃ gas to be supplied is controlled at 200 Torr (26,665 Pa) in the post-precoat process. A line I in FIG. 9, which is an example of the second embodiment, indicates the number of particles when the pressure of the NH₃ gas to be supplied is controlled at 400 Torr (53,329 Pa) in the post-precoat process. Other conditions in the post-precoat process in the second embodiment are as described above, and the time to temporarily store the NH₃ gas in the buffer tank T2 was approximately 0.7 seconds, and the time to supply the NH₃ gas stored in the buffer tank T2 into the processing chamber 1 was approximately 0.3 seconds. In the post-precoat process, a large flow of 9,000 sccm of the NH₃ gas was supplied into the processing chamber 1 in approximately 20 minutes by repeatedly supplying and stopping the NH₃ gas 1,200 times.

A line J in FIG. 9 is a reference example in which high-pressure purging of N₂ gas was performed instead of the purging of the NH₃ gas in the post-precoat process. Conditions other than the gas in the post-precoat process are the same as those in the second embodiment.

As illustrated by lines H and I in FIG. 9, particles can be reduced when the pressure of NH₃ gas in the post-precoat process of the second embodiment was 400 Torr, rather than 200 Torr. When compared with line J in FIG. 9, the high-pressure purge of NH₃ gas in the post-precoat process can reduce particles more than the high-pressure purge of N₂ gas.

From the above, particles can be decreased by controlling the pressure in the processing chamber 1 to a range of 200 Torr (26,665 Pa) to 400 Torr (53,329 Pa) when NH₃ gas is supplied in the post-precoat process.

As described above, according to the precoat method of the substrate processing apparatus and the substrate processing apparatus according to the present embodiment, particles can be decreased without reducing productivity.

The precoat method for the substrate processing apparatus and the substrate processing apparatus according to the present disclosed embodiment should be considered exemplary in all respects and not restrictive. The embodiments can be modified and improved in various forms without departing from the scope and subject matter of the appended claims. The matters described in the above embodiments may be incorporated into other configurations to the extent that they are consistent, and may be combined to the extent that they are consistent.

According to the present disclosure, a precoat method for a substrate processing apparatus and a substrate processing apparatus that can reduce particles without reducing productivity are provided.

What is claimed is:

1. A substrate processing apparatus comprising:
a processing chamber;
a gas supplier configured to supply a gas into the processing chamber; and
a controller,
wherein the controller is configured to control the gas supplier to perform:
a) supplying a fluorine-containing gas into the processing chamber to clean an inside of the processing chamber;
b) after a), supplying a reducing gas into the processing chamber to purge the inside of the processing chamber;
c) after b), supplying a raw material gas and a reducing gas into the processing chamber to form a precoat film; and
d) after c), supplying a reducing gas into the processing chamber to purge the inside of the processing chamber before depositing on a subsequent substrate,
wherein the controller is further configured to control the gas supplier to:
perform c), in a case where a flow rate of the fluorine-containing gas supplied in a) is higher than a flow rate of the raw material gas supplied in c), and
stop c), in a case where the flow rate of the fluorine-containing gas supplied in a) is equal to or lower than the flow rate of the raw material gas supplied in c).
